(19) United States
(12) Patent Application Publication
(10) Pub. No.: US 2016/0090300 A1
(43) Pub. Date: Mar. 31, 2016

(54) PIEZOELECTRIC MICROPHONE WITH INTEGRATED CMOS

(71) Applicant: INVENSENSE, INC., San Jose, CA (US)

(72) Inventors: Julius Ming-Lin Tsai, San Jose, CA (US); Michael Daneman, Campbell, CA (US)

(21) Appl. No.: 14/860,139

(22) Filed: Sep. 21, 2015

Related U.S. Application Data
(60) Provisional application No. 62/057,967, filed on Sep. 30, 2014.

(51) Int. Cl. B81B 7/02; B81C 1/00

(52) U.S. Cl. CPC B81B 7/02; B81C 1/00246; B81B 2201/0257; B81B 2203/04; B81B 2207/07; B81B 2207/094; B81B 2207/015; B81C 2203/075; B81C 2203/0714; B81C 2201/0123; B81C 2201/013; B81C 2201/0183

(57) ABSTRACT

A piezoelectric microphone and/or a piezoelectric microphone system is presented herein. In an implementation, a piezoelectric microphone includes a microelectromechanical systems (MEMS) layer and a complementary metal-oxide-semiconductor (CMOS) layer. The MEMS layer includes at least one piezoelectric layer and a conductive layer. The conductive layer is deposited on the at least one piezoelectric layer and is associated with at least one sensing electrode. The CMOS layer is deposited on the MEMS layer. Furthermore, a cavity formed in the CMOS layer includes the at least one sensing electrode

### CROSS-REFERENCE TO RELATED APPLICATION

The present application claims priority to U.S. Provisional Patent Application No. 62/057,967, filed Sep. 30, 2014, the content of which application is hereby incorporated herein by reference in its entirety.

### TECHNICAL FIELD

The subject disclosure relates generally to a piezoelectric microphone.

### BACKGROUND

In recent decades, microelectromechanical systems (MEMS) microphones have been widely adopted in consumer electronic devices due to, for example, reliability at high temperature and easy assembly. However, a large percentage of cost for producing a MEMS microphone device results from a package portion of the MEMS microphone device. It is thus desired to provide a microphone that improves upon these and other deficiencies. The above-described deficiencies are merely intended to provide an overview of some of the problems of conventional implementations, and are not intended to be exhaustive. Other problems with conventional implementations and techniques, and corresponding benefits of the various aspects described herein, may become further apparent upon review of the following description.

### SUMMARY

The following presents a simplified summary of the specification to provide a basic understanding of some aspects of the specification. This summary is not an extensive overview of the specification. It is intended to neither identify key or critical elements of the specification nor delineate any scope particular to any embodiments of the specification, or any scope of the claims. Its sole purpose is to present some concepts of the specification in a simplified form as a prelude to the more detailed description that is presented later.

In accordance with an implementation, a piezoelectric microphone includes a microelectromechanical systems (MEMS) layer and a complementary metal-oxide-semiconductor (CMOS) layer. The MEMS layer includes at least one piezoelectric layer and a conductive layer. The conductive layer is deposited on the at least one piezoelectric layer and is associated with at least one sensing electrode. The CMOS layer is deposited on the MEMS layer. Furthermore, a cavity formed in the CMOS layer includes the at least one sensing electrode.

In accordance with another implementation, a device includes a CMOS substrate and a piezoelectric microphone. The piezoelectric microphone is formed on the CMOS substrate. Furthermore, the piezoelectric microphone includes at least one piezoelectric layer and a conductive layer. The conductive layer is deposited on the at least one piezoelectric layer and is associated with at least one sensing electrode.

In accordance with yet another implementation, a method provides for depositing a first conductive layer on a MEMS substrate layer, depositing a piezoelectric layer on the first conductive layer, depositing a second conductive layer on the piezoelectric layer, and depositing a CMOS layer on the second conductive layer. In an aspect, the second conductive layer is associated with at least one sensing electrode and a cavity of the CMOS layer contains the at least one sensing electrode.

In accordance with yet another implementation, a method provides for disposing a sacrificial layer on a CMOS substrate layer, disposing a bottom electrode layer and a piezoelectric layer on the sacrificial layer, and disposing a top electrode layer on the piezoelectric layer, the sacrificial layer and a set of via structures to form an electrical connection to the CMOS substrate layer.

These and other embodiments are described in more detail below.

### BRIEF DESCRIPTION OF THE DRAWINGS

Various non-limiting embodiments are further described with reference to the accompanying drawings, in which:

FIGS. 1-3 depict a cross-sectional view of a microphone, in accordance with various aspects and implementations described herein;

FIG. 4 depicts a cross-sectional view of another microphone, in accordance with various aspects and implementations described herein;

FIG. 5 depicts a microphone package, in accordance with various aspects and implementations described herein;

FIG. 6 depicts another microphone package, in accordance with various aspects and implementations described herein;

FIG. 7 depicts yet another microphone package, in accordance with various aspects and implementations described herein;

FIG. 8 depicts yet another microphone package, in accordance with various aspects and implementations described herein;

FIG. 9 is a flowchart of an example methodology for fabricating a microphone, in accordance with various aspects and implementations described herein; and

FIG. 10 is a flowchart of another example methodology for fabricating a microphone, in accordance with various aspects and implementations described herein.

### DETAILED DESCRIPTION

### Overview

While a brief overview is provided, certain aspects of the subject disclosure are described or depicted herein for the purposes of illustration and not limitation. Thus, variations of the disclosed embodiments as suggested by the disclosed apparatuses, systems, and methodologies are intended to be encompassed within the scope of the subject matter disclosed herein.

As described above, in recent decades, microelectromechanical systems (MEMS) microphones have been widely adopted in consumer electronic devices due to, for example, reliability at high temperature and easy assembly. However, a large percentage of cost for producing a MEMS microphone device results from a package portion of the MEMS microphone device. To these and/or related ends, various aspects and embodiments associated with a microphone (e.g., a piezoelectric microphone) are described. The various embodiments of the systems, techniques, and methods of the subject disclosure are described in the context of a microphone (e.g., a piezoelectric microphone) and/or a microphone system (e.g., a piezoelectric microphone system). In an aspect, a complementary metal-oxide-semiconductor (CMOS) MEMS piezoelectric microphone can be provided. For example, a CMOS MEMS piezoelectric microphone can be provided where MEMS and CMOS are integrated together and a piezoelectric material is employed as an acoustic sensing mechanism. In one example, a MEMS microphone can be integrated with a back volume of a CMOS substrate. A pressure of the back volume can be varied based on a size of a cavity that forms the back volume. Furthermore, the back volume can be sealed or linked to environmental pressure via an acoustic port (e.g., an acoustic channel). For example, the CMOS MEMS piezoelectric microphone can include a piezoelectric sensing diaphragm with an acoustic port. In an aspect, the CMOS MEMS piezoelectric microphone can include a MEMS substrate disposed on a CMOS substrate.

In certain implementations, a microphone package can include the CMOS MEMS piezoelectric microphone. For example, a package acoustic port can be formed with film assisted molding aligned (e.g., partially aligned) with an acoustic port of the CMOS MEMS piezoelectric microphone. In another example, the CMOS MEMS piezoelectric microphone can be formed into a chip scale package where solder balls are disposed and form electrical coupling. In yet another example, a top port microphone module can be formed with the CMOS MEMS piezoelectric microphone. In yet another example, a bottom port microphone module can be formed with the CMOS MEMS piezoelectric microphone (e.g., with a package volume as a back volume) by aligning a package acoustic port with an acoustic port of the CMOS MEMS piezoelectric microphone. As such, CMOS and MEMS can be integrated to alleviate need for a packaged back volume. Furthermore, an internal back cavity for a microphone can be absorbed during microphone chip processing. Moreover, a cheaper microphone package solution can be realized. However, as further detailed below, various exemplary implementations can be applied to other areas of a microphone (e.g., a CMOS MEMS piezoelectric microphone), without departing from the subject matter described herein.

### Exemplary Embodiments

Various aspects or features of the subject disclosure are described with reference to the drawings, wherein like reference numerals are used to refer to like elements throughout. In this specification, numerous specific details are set forth in order to provide a thorough understanding of the subject disclosure. It should be understood, however, that the certain aspects of disclosure may be practiced without these specific details, or with other methods, components, parameters, etc. In other instances, well-known structures and devices are shown in block diagram form to facilitate description and illustration of the various embodiments.

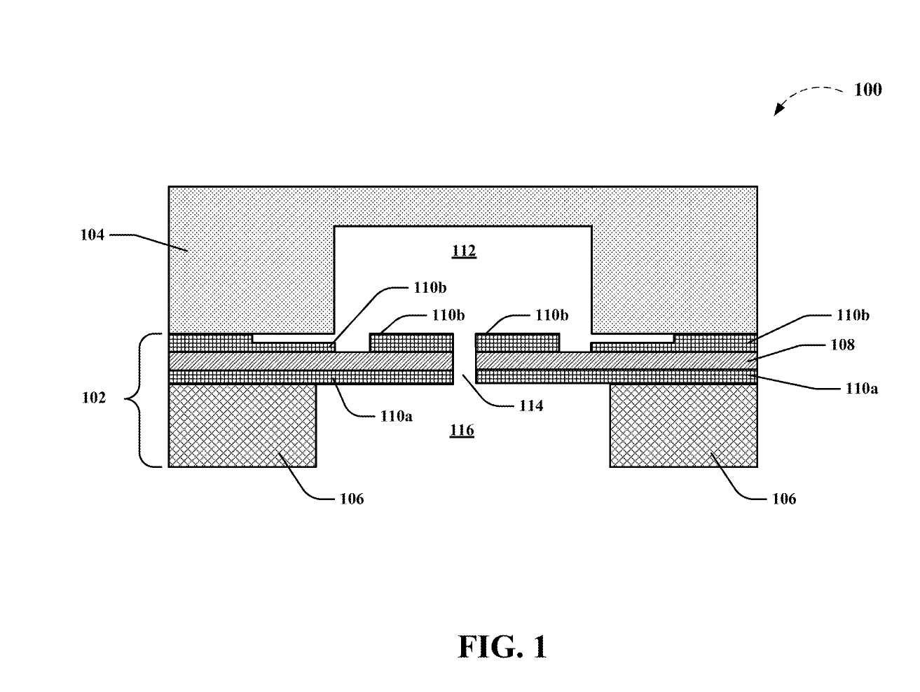

FIG. 1 depicts a cross-sectional view of a microphone 100, according to various non-limiting aspects of the subject disclosure. The microphone 100 can be, for example, a piezoelectric microphone. However, it is to be appreciated that the microphone 100 can be implemented as a different type of microphone. The microphone 100 includes a microelectromechanical systems (MEMS) layer 102 and a complementary metal-oxide-semiconductor (CMOS) layer 104. For example, the microphone 100 can be a CMOS MEMS integrated device that can form a piezoelectric microphone (e.g., a CMOS MEMS integrated piezoelectric microphone). The microphone 100 can provide integration of CMOS and MEMS to alleviate the need for a packaged back volume. Moreover, with the microphone 100, an internal back cavity can be absorbed during chip processing. Accordingly, a cheaper microphone package solution can be realized.

The MEMS layer 102 can include, for example, a substrate layer 106, a piezoelectric layer 108 and a first conductive layer 110a and/or a second conductive layer 110b. The substrate layer 106 can be a handle layer of the MEMS layer 102. In one example, the substrate layer 106 can be a silicon layer. The first conductive layer 110a can be deposited on the substrate layer 106. Furthermore, the piezoelectric layer 108 can be deposited on the first conductive layer 110a. The second conductive layer 110b can be deposited on the piezoelectric layer 108. The first conductive layer 110a and the second conductive layer 110b can be, for example, aluminum layers. However, it is to be appreciated that the first conductive layer 110a and the second conductive layer 110b can include a different type of metal.

In an aspect, the second conductive layer 110b can be associated with at least one sensing electrode. For example, the first conductive layer 110a can be a bottom electrode layer and the second conductive layer 110b can be a top electrode layer. The at least one sensing electrode associated with the second conductive layer 110b can be configured, for example, for differential sensing associated with an acoustic signal. Furthermore, the at least one sensing electrode associated with the second conductive layer 110b can be associated with a voltage output generated in response to an acoustic signal. The CMOS layer 104 can be deposited on the MEMS layer 102. For example, the CMOS layer 104 can be deposited on the second conductive layer 110b (e.g., the second conductive layer 110b can be bonded to the CMOS layer 104). Moreover, the CMOS layer 104 can be electrically connected to the MEMS layer 102. In another aspect, MEMS layer 102 can be bonded to the CMOS layer 104 via eutectic bonding, metal compression bonding, conductive polymer bonding, or another bonding technique. A bond between the MEMS layer 102 and the CMOS layer 104 can provide an acoustic seal for the microphone 100. The second conductive layer 110b can be divided into a plurality of portions. For example, as shown in FIG. 1, the second conductive layer 110b can be divided into a first portion, a second portion, a third portion and a fourth portion. However, it is to be appreciated that the second conductive layer 110b can be divided into a different number of portions (e.g., a first portion and a second portion, etc.).

The CMOS layer 104 can include a cavity 112. In one example, the cavity 112 can be a back volume (e.g., a back volume for the microphone 100). The cavity 112 can include the at least one sensing electrode associated with the second conductive layer 110b. Furthermore, the cavity 112 can be acoustically coupled to the MEMS layer 102. In an aspect, the MEMS layer 102 can include a moveable portion that moves in response to an acoustic signal. For example, the piezoelectric layer 108, the first conductive layer 110a and/or the second conductive layer 110b can be a moveable portion of the MEMS layer 102 that moves in response to an acoustic signal (e.g., to facilitate converting vibrations associated with the acoustic signal into an electrical signal). An acoustic signal can be received (e.g., by the at least one sensing electrode associated with the second conductive layer 110b) via the cavity 112 and a pressure equalization channel 114. The pressure equalization channel 114 can be an opening between the cavity 112 and an acoustic port 116. Furthermore, the pressure equalization channel 114 can divide the first conductive layer 110a, the piezoelectric layer 108 and/or the second conductive layer 110b in to a first portion and a second portion. For example, the pressure equalization channel 114 can separate a first portion of the first conductive layer 110a, the piezoelectric layer 108 and/or the second conductive layer 110b from a second portion of the first conductive layer 110a, the piezoelectric layer 108 and/or the second conductive layer 110b. As such, an acoustic signal can enter the cavity 112 via the acoustic port 116 and the pressure equalization channel 114. In an aspect, the acoustic port 116 can be formed via an etching process through the first substrate layer 106a (e.g., a supporting layer) of the MEMS layer 102. Additionally or alternatively, the cavity 112 (e.g., a back volume) and/or the pressure equalization channel 114 can be formed via an etching process. In one example, the CMOS layer 104 can be an integrated circuit substrate.

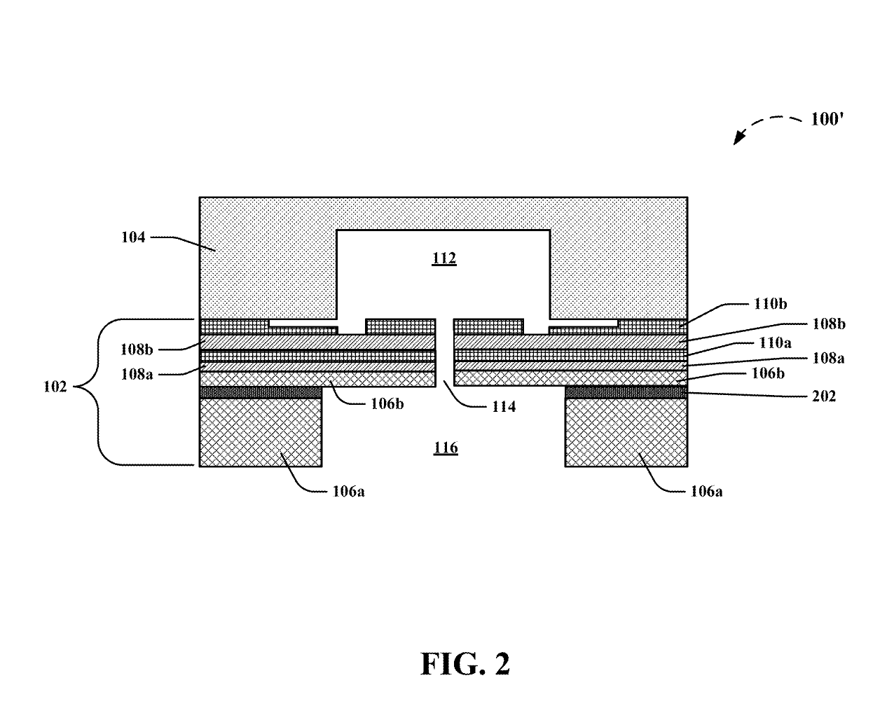

FIG. 2 depicts a cross-sectional view of a microphone 100′, according to various non-limiting aspects of the subject disclosure. The microphone 100′ can be an alternate embodiment of the microphone 100. The microphone 100′ can provide integration of CMOS and MEMS to alleviate the need for a packaged back volume. Moreover, with the microphone 100′, an internal back cavity can be absorbed during chip processing. Accordingly, a cheaper microphone package solution can be realized. The microphone 100′ includes the MEMS layer 102 and the CMOS layer 104. The MEMS layer 102 can include, for example, a first substrate layer 106a, an oxide layer 202, a second substrate layer 106b, a first piezoelectric layer 108a, a second piezoelectric layer 108b, the first conductive layer 110a and/or the second conductive layer 110b. The oxide layer 202 can be deposited on the first substrate layer 106a. Furthermore, the second substrate layer 106b can be deposited on the oxide layer 202. As such, the oxide layer 202 can be deposited between the first substrate layer 106a of the MEMS layer 102 and the second substrate layer 106b of the MEMS layer 102. In one example, the first substrate layer 106a and the second substrate layer 106b can be silicon layers. Furthermore, the oxide layer 202 can be, for example, a silicon dioxide layer. As such, the first substrate layer 106a, the oxide layer 202 and the second substrate layer 106b can form a Silicon on Insulator (SOI) wafer.

The first piezoelectric layer 108a can be deposited on the second substrate layer 106b. Furthermore, the first conductive layer 110a can be deposited on the first piezoelectric layer 108a. The second piezoelectric layer 108b can be deposited on the first conductive layer 110a. The first piezoelectric layer 108a and the second piezoelectric layer 108b can be, for example, aluminum nitride (AlN) layers. In one example, the first piezoelectric layer 108a and the second piezoelectric layer 108b can form a set of stacking layers (e.g., a set of AlN stacking layers). For example, the first piezoelectric layer 108a can be an AlN seed layer in contact with the second substrate layer 106b (e.g., in contact with a silicon device layer on SOI, such as the SOI of the MEMS layer 102, etc.), the first conductive layer 110a can be formed on the first piezoelectric layer 108a, the second piezoelectric layer 108b can be formed on the first conductive layer 110a, and the second conductive layer 110b can be formed on the second piezoelectric layer 108b. In an implementation, the MEMS layer 102 (e.g., the first substrate layer 106a) can be bonded to another layer (e.g., an integrated circuit substrate) to form electrical coupling and/or acoustic sealing. Moreover, in an aspect, the cavity 112 (e.g., a back volume for the microphone 100′) can be formed by etching (e.g., partially etching) the CMOS layer 104 (e.g., a supporting silicon layer portion of the CMOS layer 104) and voids in the MEMS layer 102. The pressure equalization channel 114 can also be formed by etching through second substrate layer 106b, the first piezoelectric layer 108a, the first conductive layer 110a, the second piezoelectric layer 108b and the second conductive layer 110b (e.g., an AlN stacking layer and a silicon device layer of the MEMS layer 102) so that an air flow passage is created between environment pressure and the cavity 112 (e.g., the back volume for the microphone 100′). Therefore, once an acoustic signal excites the second piezoelectric layer 108b, a charge can be generated, amplified and/or processed by circuitry associated with the CMOS layer 104.

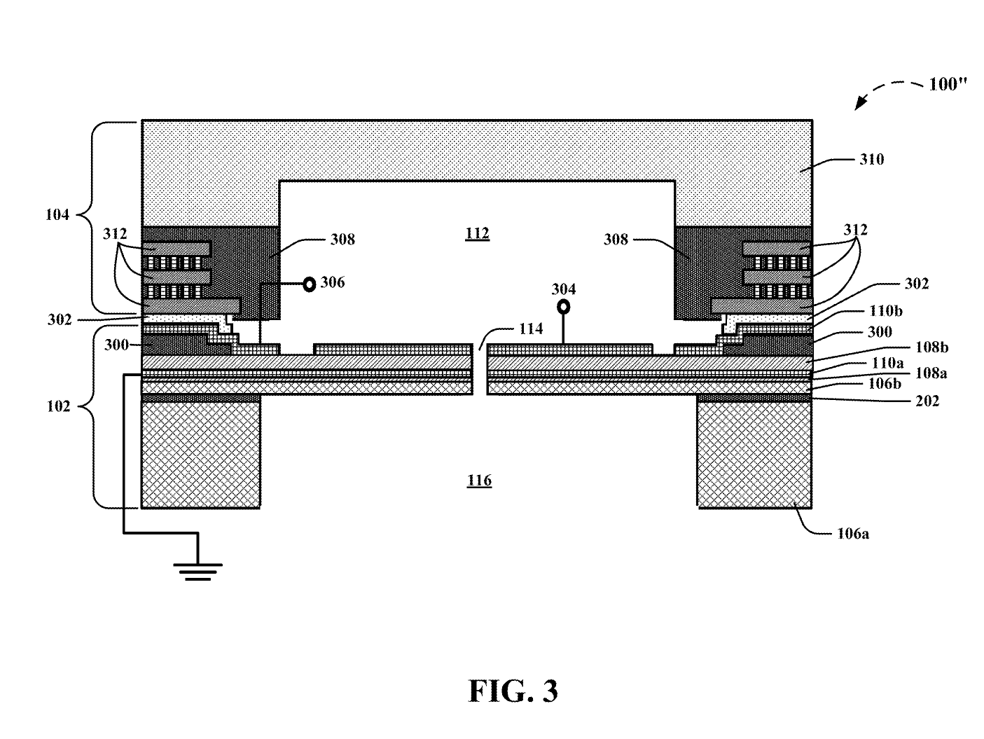

FIG. 3 depicts a cross-sectional view of a microphone 100″, according to various non-limiting aspects of the subject disclosure. The microphone 100″ can be an alternate embodiment of the microphone 100 and/or the microphone 100′. The microphone 100″ can provide integration of CMOS and MEMS to alleviate the need for a packaged back volume. Moreover, with the microphone 100″, an internal back cavity can be absorbed during chip processing. Accordingly, a cheaper microphone package solution can be realized. The microphone 100″ includes the MEMS layer 102 and the CMOS layer 104. The MEMS layer 102 can include, for example, the first substrate layer 106a, the oxide layer 202, the second substrate layer 106b, the first piezoelectric layer 108a, the second piezoelectric layer 108b, the first conductive layer 110a and/or the second conductive layer 110b. In certain implementations, an oxide layer 300 can be deposited between a portion of the second piezoelectric layer 108b and a portion of the second conductive layer 110b. The oxide layer 300 can be, for example, a silicon dioxide layer. Furthermore, in certain implementations, the MEMS layer 102 can be coupled to the CMOS layer 104 via a bonding layer 302. For example, the bonding layer 302 can provide wafer bonding between the MEMS layer 102 and the CMOS layer 104. The bonding layer 302 can be formed via eutectic bonding, metal compression bonding, conductive polymer bonding, or another bonding technique. In one example, the bonding layer 302 can be a germanium layer.

The second conductive layer 110b can be associated with at least one sensing electrode. In an implementation, the second conductive layer 110b can be associated with a first sensing electrode 304 and a second sensing electrode 306. For example, the first sensing electrode 304 can be deposited on a first portion of the second piezoelectric layer 108b and the second sensing electrode 306 can be deposited on a second portion of the second piezoelectric layer 108b. The second portion of the second piezoelectric layer 108b can be separated from the first portion of the second piezoelectric layer 108b via the pressure equalization channel 114. However, it is to be appreciated that the second conductive layer 110b can be associated with more than two sensing electrodes. Moreover, in certain implementations, the first conductive layer 110a can additionally or alternatively be associated with at least one sensing electrode. For example, the first conductive layer 110a can be associated with a third sensing electrode in addition to the first sensing electrode 304 and the second sensing electrode 306. In an aspect, the first conductive layer 110a can be grounded and the second conductive layer 110b can be associated with an electrical charge. In another aspect, the acoustic port 116 can receive a pressure load. For example, the pressure load can be associated with environmental pressure. In another example, the pressure load can be associated with an acoustic signal. In another aspect, the CMOS layer 104 can include an oxide layer 308 and a substrate layer 310. The oxide layer 308 can be, for example, a silicon dioxide layer. The substrate layer 310 can be, for example, a silicon layer. The oxide layer 308 of the CMOS layer 104 can include a set of via structures 312 to facilitate an electrical connection between the MEMS layer 102 (e.g., the second conductive layer 110b) and the CMOS layer 104 (e.g., the substrate layer 310). A via structure from the set of via structures 312 can include a set of metal layers and a set of via connections.

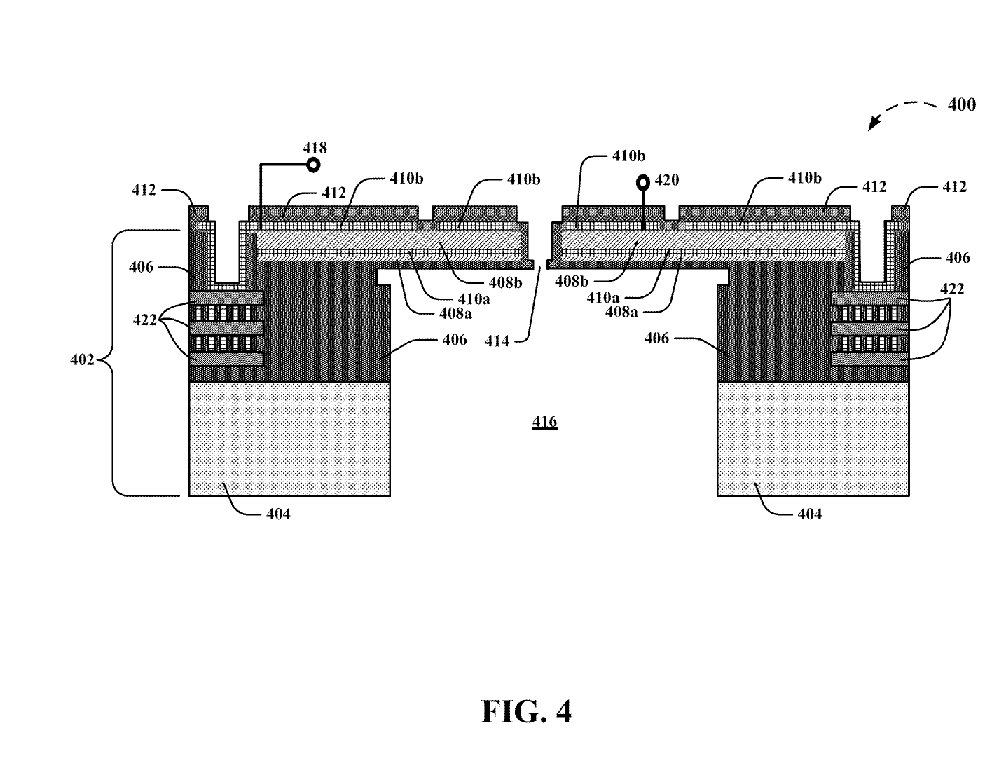

FIG. 4 depicts a cross-sectional view of a microphone 400, according to various non-limiting aspects of the subject disclosure. In one example, the microphone 400 can be a piezoelectric microphone (e.g., a MEMS piezoelectric microphone). The microphone 400 includes a CMOS layer 402. The microphone 400 can provide direct integration of a microphone (e.g., a MEMS piezoelectric microphone) on a CMOS substrate. For example, microphone (e.g., a piezoelectric microphone) can be formed directly on top of a substrate layer 404 of the CMOS layer 402. The microphone 400 can provide integration of CMOS and MEMS to alleviate the need for a packaged back volume. Moreover, with the microphone 400, an internal back cavity can be absorbed during chip processing. Accordingly, a cheaper microphone package solution can be realized.

The substrate layer 404 can be, for example, a silicon layer. An oxide layer 406 can be deposited on the substrate layer 404. The oxide layer 406 can be, for example, a silicon dioxide layer. In one example, the oxide layer 406 can include amorphous silicon. Furthermore, the oxide layer 406 can be a sacrificial layer. The oxide layer 406 can be disposed and/or patterned on top of the substrate layer 404. In an aspect, the oxide layer 406 can undergo structure layer deposition and/or planarization. For example, physical vapor deposition and/or the chemical vapor deposition can be performed. Additionally or alternatively, one or more planarization processes (e.g., one or more chemical-mechanical planarization processes) can be performed. Moreover, a first piezoelectric layer 408a can be deposited on a top surface of the oxide layer 406. A first conductive layer 410a can be deposited on the first piezoelectric layer 408a, a second piezoelectric layer 408b can be deposited on the first conductive layer 410a, and a second conductive layer 410b can be deposited on the second piezoelectric layer 408b. The first piezoelectric layer 408a, the first conductive layer 410a, the second piezoelectric layer 408b and/or the second conductive layer 410b can also be patterned. In one example, the first piezoelectric layer 408a and the second piezoelectric layer 408b can be aluminum nitride layers.

The first conductive layer 410a can be a bottom electrode layer and the second conductive layer 410b can be a top electrode layer. Furthermore, the first conductive layer 410a and the second conductive layer 410b can be, for example, aluminum layers. However, it is to be appreciated that the first conductive layer 410a and the second conductive layer 410b can comprise a different type of metal. In an aspect, a set of via structures 422 can be formed in the CMOS layer 104 (e.g., in the oxide layer 406). A via structure from the set of via structures 422 can include a set of metal layers and a set of via connections. The set of via structures 422 can be electrically coupled to the second conductive layer 410b. A pressure equalization channel 414 and an acoustic port 416 can also be formed. For example, the pressure equalization channel 414 can be formed via an etching process. Furthermore, the acoustic port 416 can be formed via an etching process through the substrate layer 404 (e.g., a supporting layer) of the CMOS layer 402. In one example, the acoustic port 416 can be an integrated back volume from a bottom surface of the CMOS layer 402. In an aspect, the second conductive layer 410b can be associated with a first sensing electrode 418 and a second sensing electrode 420. In another aspect, the second conductive layer 410b can be disposed an/or etched to form an electrical connection to the substrate layer 404 of the CMOS layer 402. For example, the first sensing electrode 418 and the second sensing electrode 420 can be electrically coupled the substrate layer 404 of the CMOS layer 402. In certain implementations, a passivation layer 412 can be deposited on the second conductive layer 410b. For example, the passivation layer 412 can be disposed and/or etched to form protection against humidity on a top surface of the CMOS layer 402. In one example, the passivation layer 412 can include silicon nitride.

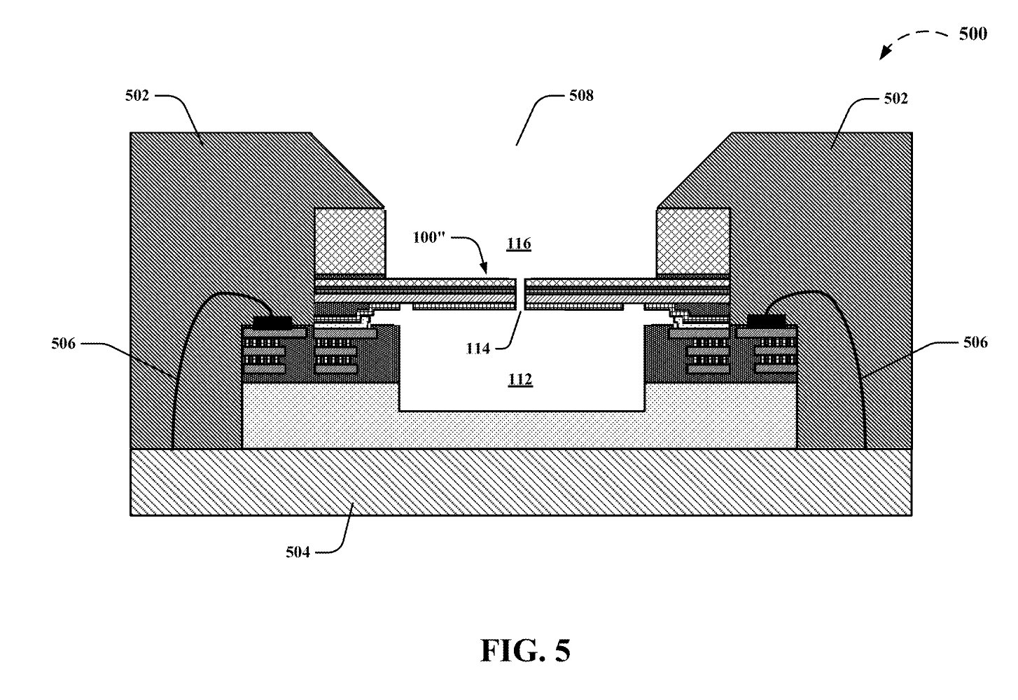

FIG. 5 depicts a cross-sectional view of a system 500, according to various non-limiting aspects of the subject disclosure. The system 500 can be a package solution for a microphone (e.g., a piezoelectric microphone). For example, the system 500 can be a package solution for the microphone 100″. However, it is to be appreciated that the system 500 can be a package solution for another microphone (e.g., the microphone 100, the microphone 100′, the microphone 400, etc.). In one example, the system 500 can be a quad-flat no-lead (QFN) package. The system 500 can include a molding 502. The molding 502 can be a molding compound such as, for example, a film assisted molding. In one example, the molding 502 can be a plastic molding. The microphone 100″ can be disposed on a lead frame 504 (e.g., for further electrical leads). A wire-bond 506 can connect (e.g., electrically couple) the microphone 100″ to metal leads of the lead frame 504. In an aspect, molding 502 can be injected to protect the microphone 100″, the lead frame 504 and/or the wire-bond 506. In another aspect, a package acoustic port 508 can be formed, for example, by film-assisted molding during an injection process (e.g., to prevent the molding 502 from blocking the acoustic port 116 of the microphone 100″). Therefore, the microphone 100, the microphone 100′, the microphone 100″ or the microphone 400 can be integrated with a molding.

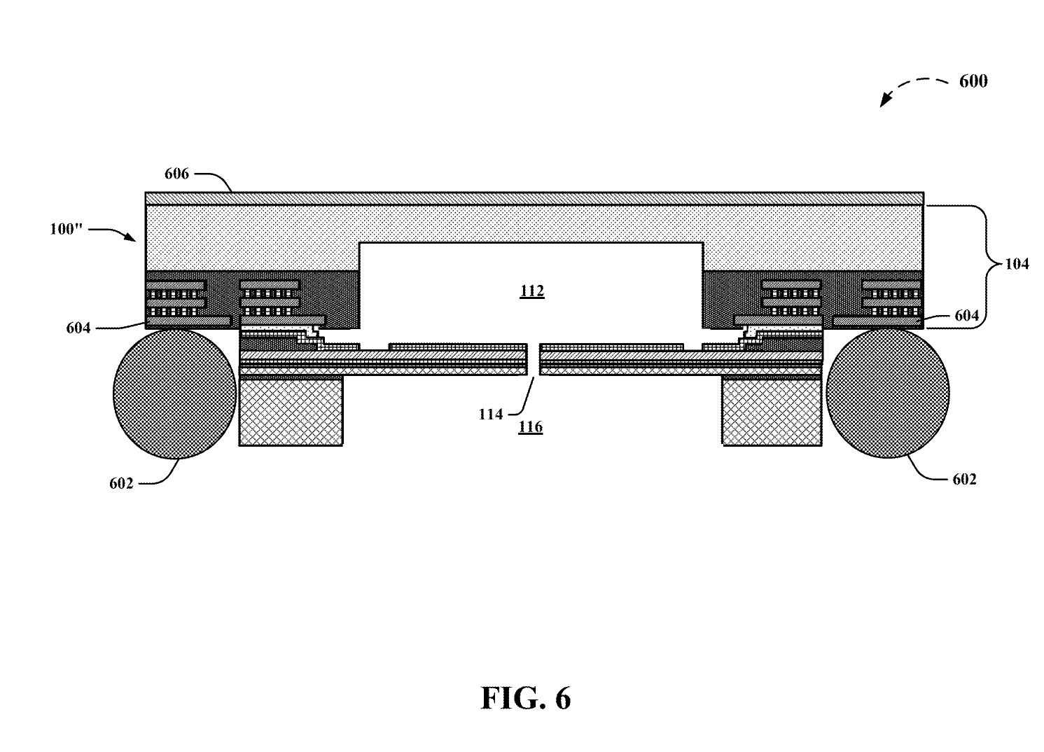

FIG. 6 depicts a cross-sectional view of a system 600, according to various non-limiting aspects of the subject disclosure. The system 600 can be a package solution for a microphone (e.g., a piezoelectric microphone). For example, the system 600 can be a package solution for the microphone 100″. However, it is to be appreciated that the system 600 can be a package solution for another microphone (e.g., the microphone 100, the microphone 100′, the microphone 400, etc.). In one example, the system 600 can be a chip scale package (CSP). In the system 600, the microphone 100″ is the package and solder ball(s) 602 provide electrical coupling to another device (e.g., an integrated chip substrate, etc.). In an aspect, the CMOS layer 104 can include a set of electrical contact pads 604 associated with the solder ball(s) to facilitate electrical coupling to another device. In certain implementations, an acoustic seal layer 606 can be disposed on a bottom surface of the microphone 100″ (e.g., a surface of the CMOS layer 104 of the microphone 100″). For example, the acoustic seal layer 606 can be an acoustic seal for the CMOS layer 104 and/or the microphone 100″. In one example, the acoustic seal layer 606 can form a sealed back volume in a scenario where the cavity 112 (e.g., the back volume) is formed by etching (e.g., partially etching) silicon from the bottom surface of the microphone 100″ (e.g., a surface of the CMOS layer 104 of the microphone 100″).

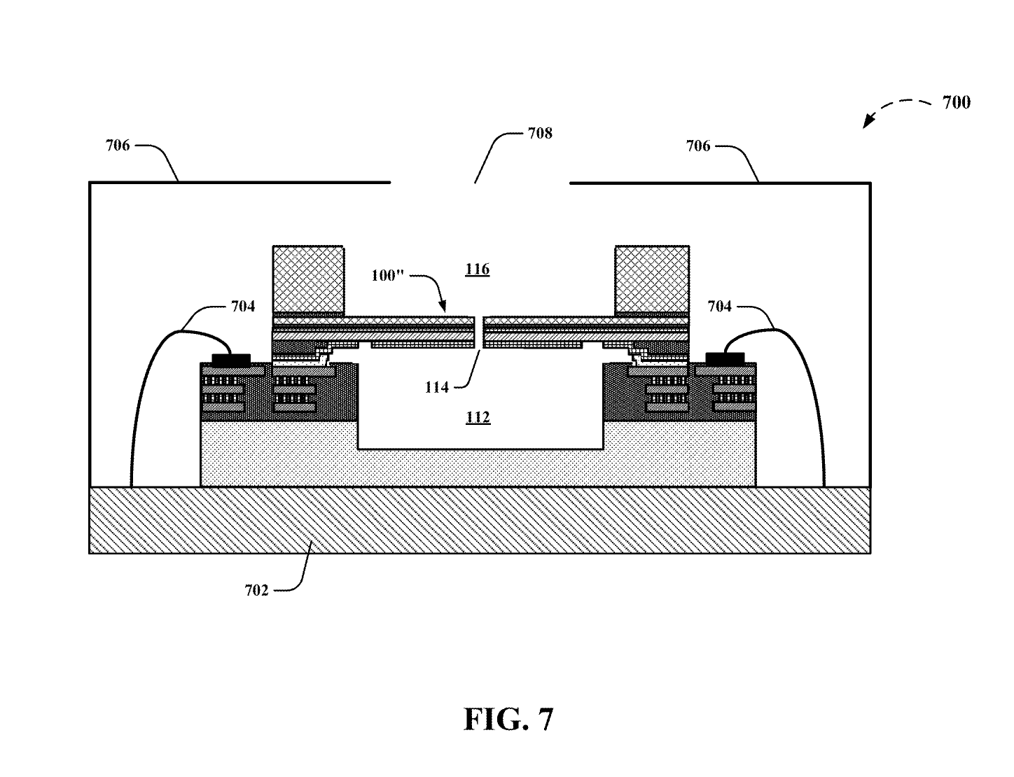

FIG. 7 depicts a cross-sectional view of a system 700, according to various non-limiting aspects of the subject disclosure. The system 700 can be a package solution for a microphone (e.g., a piezoelectric microphone). For example, the system 700 can be a package solution for the microphone 100″. However, it is to be appreciated that the system 700 can be a package solution for another microphone (e.g., the microphone 100, the microphone 100′, the microphone 400, etc.). In one example, the system 700 can be top port microphone package. The system 700 can include a laminate layer 702. The laminate layer 702 can be a laminate anchor base for the microphone 100″. For example, the microphone 100″ can be disposed on the laminate layer 702. A wire-bond 704 can connect (e.g., electrically couple) the microphone 100″ to metal leads of the laminate layer 702. A lid 706 with an acoustic port opening 708 can be disposed on top of the laminate layer 702 (e.g., to form a protective enclosing for the microphone 100″). As such, a back volume for the microphone 100″ can be integrated within the microphone 100″. Moreover, the microphone 100, the microphone 100′, the microphone 100″ or the microphone 400 can be integrated with a substrate (e.g., the laminate layer) and a lid (e.g., the lid 706) that comprises an acoustic port opening (e.g., the acoustic port opening 708). In certain implementations, the system 500 and/or the system 600 can additionally include the lid 706 with the acoustic port opening 708.

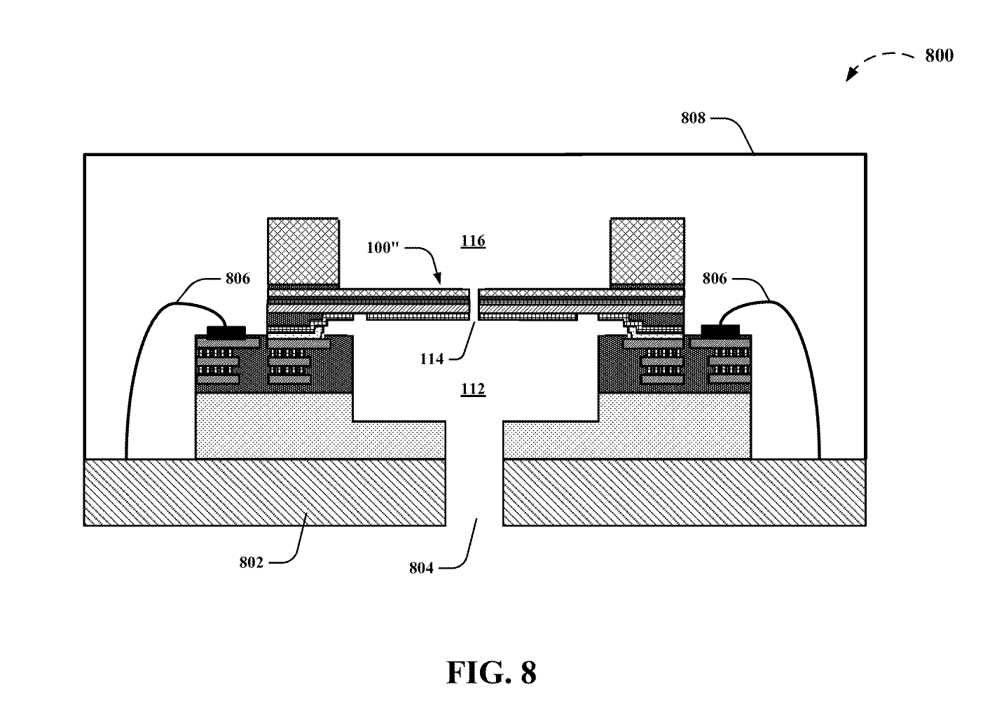

FIG. 8 depicts a cross-sectional view of a system 800, according to various non-limiting aspects of the subject disclosure. The system 800 can be a package solution for a microphone (e.g., a piezoelectric microphone). For example, the system 800 can be a package solution for the microphone 100″. However, it is to be appreciated that the system 800 can be a package solution for another microphone (e.g., the microphone 100, the microphone 100′, the microphone 400, etc.). In one example, the system 800 can be bottom port microphone package. The system 800 can include a laminate layer 802. The laminate layer 802 can be a laminate anchor base for the microphone 100″. For example, the microphone 100″ can be disposed on the laminate layer 802. The laminate layer 802 can include an acoustic port opening 804. The acoustic port opening 804 can be aligned with the pressure equalization channel 114 and/or the acoustic port 116 of the microphone 100″. A wire-bond 806 can connect (e.g., electrically couple) the microphone 100″ to metal leads of the laminate layer 802. Furthermore, a lid 808 can be disposed on top of the laminate layer 802 (e.g., to form a protective enclosing for the microphone 100″). As such, a back volume for the microphone 100″ can be formed by a volume contained by the lid 808 and the laminate layer 802. Moreover, the microphone 100, the microphone 100′, the microphone 100″ or the microphone 400 can be integrated with a lid (e.g., the lid 808) and a substrate (e.g., the laminate layer 802) that comprises an acoustic port opening (e.g., the acoustic port opening 804). As shown in FIG. 8, the lid 808 can be implemented without an acoustic port opening. However, in certain implementations, the lid 808 can include an acoustic port opening (e.g., acoustic port opening 708).

While various embodiments for a microphone (e.g., a CMOS MEMS integrated piezoelectric microphone) according to aspects of the subject disclosure have been described herein for purposes of illustration, and not limitation, it can be appreciated that the subject disclosure is not so limited. Various implementations can be applied to other microphones, without departing from the subject matter described herein. For instance, it can be appreciated that other microphone applications requiring an improved microphone package solution can employ aspects of the subject disclosure. Furthermore, various exemplary implementations of systems as described herein can additionally, or alternatively, include other features, functionalities and/or components and so on.

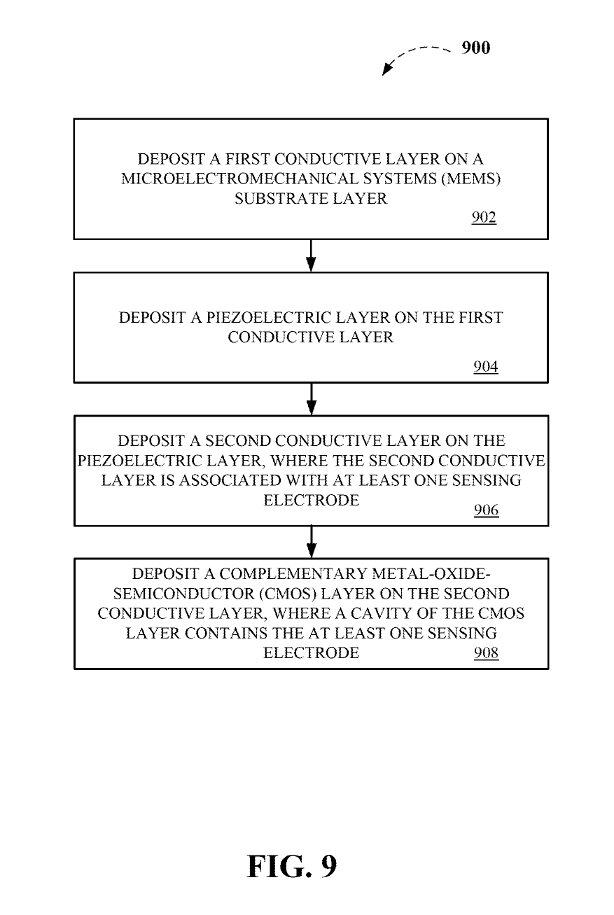

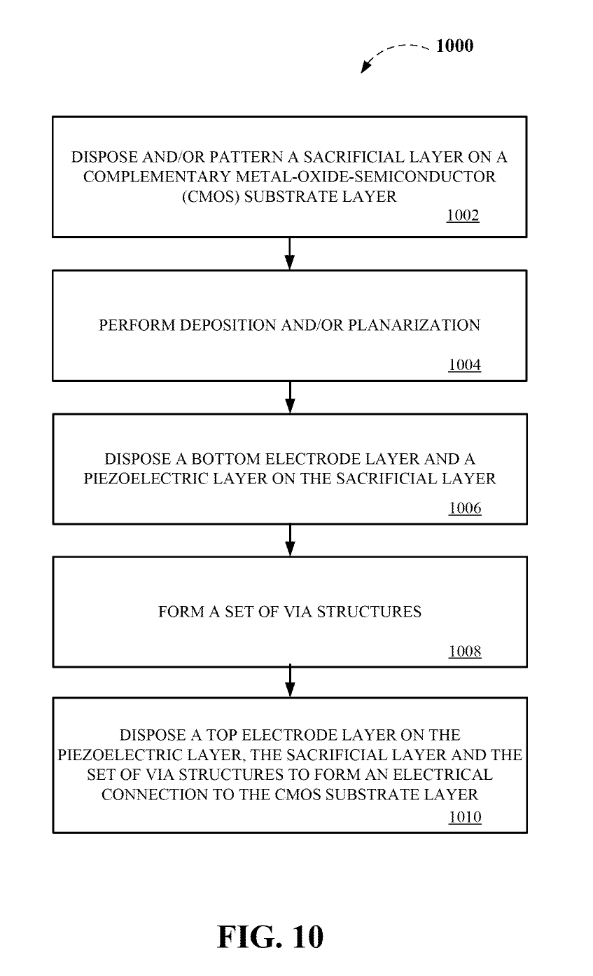

In view of the subject matter described supra, methods that can be implemented in accordance with the subject disclosure will be better appreciated with reference to the flowcharts of FIGS. 9-10. While for purposes of simplicity of explanation, the methods are shown and described as a series of blocks, it is to be understood and appreciated that such illustrations or corresponding descriptions are not limited by the order of the blocks, as some blocks may occur in different orders and/or concurrently with other blocks from what is depicted and described herein. Any non-sequential, or branched, flow illustrated via a flowchart should be understood to indicate that various other branches, flow paths, and orders of the blocks, can be implemented which achieve the same or a similar result. Moreover, not all illustrated blocks may be required to implement the methods described hereinafter.

### Exemplary Methods

FIG. 9 depicts an exemplary flowchart of a non-limiting method 900 for fabricating a microphone (e.g., CMOS MEMS integrated piezoelectric microphone), according to various non-limiting aspects of the subject disclosure. In an aspect, the method 900 can be associated with the microphone 100, the microphone 100′ and/or the microphone 100″. Initially, at 902, a first conductive layer is deposited on a microelectromechanical systems (MEMS) substrate layer. The first conductive layer can be, for example, an aluminum layer. Furthermore, the first conductive layer can be a bottom electrode layer. In an implementation, the MEMS substrate layer can include an oxide layer between a first MEMS substrate layer (e.g., a first silicon layer) and a second MEMS substrate layer (e.g., a second silicon layer). The oxide layer can be, for example, a silicon dioxide layer. At 904, a piezoelectric layer is deposited on the first conductive layer. The piezoelectric layer can be, for example, an aluminum nitride layer. In an implementation, another piezoelectric layer can be deposited between the MEMS substrate layer and the first conductive layer. The other piezoelectric layer can be, for example, an aluminum nitride layer. At 906, a second conductive layer is deposited on the piezoelectric layer, where the second conductive layer is associated with at least one sensing electrode. The second conductive layer can be, for example, an aluminum layer. Furthermore, the second conductive layer can be a top electrode layer. At 908, a complementary metal-oxide-semiconductor (CMOS) layer is deposited on the second conductive layer, where a cavity of the CMOS layer contains the at least one sensing electrode. For example, the cavity of the CMOS layer can be a hollow space in the CMOS layer that contains the at least one sensing electrode. The at least one sensing electrode can be configured for differential sensing associated with an acoustic signal. The cavity of the CMOS layer can be, for example, a back volume for a microphone. The cavity can be formed via an etching process. In an implementation, the CMOS layer can include an oxide layer and a CMOS substrate layer (e.g., a silicon layer). Additionally or alternatively, the CMOS layer can include a set of via structures. In an aspect, the method 900 can further include forming the cavity of the CMOS layer (e.g., via an etching technique). Additionally or alternatively, the method 900 can include forming an acoustic port in the MEMS substrate layer (e.g., via an etching technique) and/or forming a pressure equalization channel in the first conductive layer, the piezoelectric layer and the second conductive layer (e.g., via an etching technique). The pressure equalization channel can acoustically couple the acoustic port to the cavity. Therefore, an acoustic signal can be received (e.g., by the at least one sensing electrode) via the acoustic port, the pressure equalization channel and/or the cavity.

FIG. 10 depicts an exemplary flowchart of a non-limiting method 1000 for fabricating a microphone (e.g., CMOS MEMS integrated piezoelectric microphone), according to various non-limiting aspects of the subject disclosure. In an aspect, the method 1000 can be associated with the microphone 400. Initially, at 1002, a sacrificial layer is disposed and/or patterned on a complementary metal-oxide-semiconductor (CMOS) substrate layer. The sacrificial layer can be, for example, an oxide layer (e.g., a silicon dioxide layer, an amorphous silicon layer, etc.). At 1004, deposition and/or planarization is performed. For example, physical vapor deposition and/or the chemical vapor deposition can be performed. Additionally or alternatively, one or more planarization processes (e.g., one or more chemical-mechanical planarization processes) can be performed. At 1006, a bottom electrode layer and a piezoelectric layer are disposed on the sacrificial layer. For example, the bottom electrode layer can be disposed on the sacrificial layer. Furthermore, the piezoelectric layer can be disposed on the bottom electrode layer. The bottom electrode layer can be, for example, a first conductive layer (e.g., a first aluminum layer). The piezoelectric layer can be, for example, an aluminum nitride layer. At 1008, a set of via structures is formed. A via structure from the set of via structures can include a set of metal layers and/or a set of via connections. In one example, the set of via structures can be formed within the sacrificial layer. At 1010, a top electrode layer is disposed on the piezoelectric layer, the sacrificial layer and the set of via structures to form an electrical connection to the CMOS substrate layer. For example, the top electrode layer can be electrically coupled to the sacrificial layer and/or the set of via structures. The top electrode layer can be, for example, a second conductive layer (e.g., a second aluminum layer).

It is to be appreciated that various exemplary implementations of exemplary methods 900 and 1000 as described can additionally, or alternatively, include other process steps for fabricating a microphone and/or a microphone system, as further detailed herein, for example, regarding FIGS. 1-8.

What has been described above includes examples of the embodiments of the subject disclosure. It is, of course, not possible to describe every conceivable combination of configurations, components, and/or methods for purposes of describing the claimed subject matter, but it is to be appreciated that many further combinations and permutations of the various embodiments are possible. Accordingly, the claimed subject matter is intended to embrace all such alterations, modifications, and variations that fall within the spirit and scope of the appended claims. While specific embodiments and examples are described in subject disclosure for illustrative purposes, various modifications are possible that are considered within the scope of such embodiments and examples, as those skilled in the relevant art can recognize.

In addition, the words “example” or “exemplary” is used herein to mean serving as an example, instance, or illustration. Any aspect or design described herein as “exemplary” is not necessarily to be construed as preferred or advantageous over other aspects or designs. Rather, use of the word, “exemplary,” is intended to present concepts in a concrete fashion. As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form.

In addition, while an aspect may have been disclosed with respect to only one of several embodiments, such feature may be combined with one or more other features of the other embodiments as may be desired and advantageous for any given or particular application. Furthermore, to the extent that the terms “includes,” “including,” “has,” “contains,” variants thereof, and other similar words are used in either the detailed description or the claims, these terms are intended to be inclusive in a manner similar to the term “comprising” as an open transition word without precluding any additional or other elements.

What is claimed is:

1. A piezoelectric microphone, comprising:
a microelectromechanical systems (MEMS) layer, comprising:
at least one piezoelectric layer; and
a conductive layer that is deposited on the at least one piezoelectric layer and is associated with at least one sensing electrode; and
a complementary metal-oxide-semiconductor (CMOS) layer deposited on the MEMS layer, wherein a cavity formed in the CMOS layer comprises the at least one sensing electrode.

2. The piezoelectric microphone of claim 1, wherein the at least one piezoelectric layer and the conductive layer are a moveable portion of the MEMS layer that moves in response to an acoustic signal.

3. The piezoelectric microphone of claim 1, wherein the MEMS layer is electrically coupled to the CMOS layer.

4. The piezoelectric microphone of claim 1, wherein the cavity formed in the CMOS layer is acoustically coupled to the MEMS layer.

5. The piezoelectric microphone of claim 1, wherein the cavity formed in the CMOS layer is a back volume for the piezoelectric microphone.

6. The piezoelectric microphone of claim 1, wherein the at least one sensing electrode comprises a first sensing electrode on a first portion of the at least one piezoelectric layer and a second sensing electrode on a second portion of the at least one piezoelectric layer that is separated from the first portion of the at least one piezoelectric layer via a pressure equalization channel.

7. The piezoelectric microphone of claim 1, wherein the at least one sensing electrode is configured for differential sensing.

8. The piezoelectric microphone of claim 1, wherein a pressure equalization channel separates a first portion of the at least one piezoelectric layer and the conductive layer from a second portion of the at least one piezoelectric layer and the conductive layer.

9. The piezoelectric microphone of claim 8, wherein an acoustic signal is received by the at least one sensing electrode via the pressure equalization channel and the cavity.

10. The piezoelectric microphone of claim 1, wherein the MEMS layer further comprises:
an oxide layer deposited between a first substrate of the MEMS layer and a second substrate of the MEMS layer.

11. The piezoelectric microphone of claim 1, wherein the conductive layer is bonded to the CMOS layer.

12. The piezoelectric microphone of claim 1, wherein the MEMS layer is bonded to the CMOS layer via eutectic bonding, metal compression bonding, or conductive polymer bonding.

13. The piezoelectric microphone of claim 1, wherein a bond between the MEMS layer and the CMOS layer provides an acoustic seal for the piezoelectric microphone.

14. The piezoelectric microphone of claim 1, wherein an acoustic port is formed in a portion of the MEMS layer.

15. The piezoelectric microphone of claim 1, wherein the CMOS layer comprises a set of electrical contact pads associated with solder balls.

16. The piezoelectric microphone of claim 1, wherein the piezoelectric microphone is integrated with a molding.

17. The piezoelectric microphone of claim 1, wherein the piezoelectric microphone is integrated with a substrate and a lid that comprises an acoustic port opening.

18. The piezoelectric microphone of claim 1, wherein the piezoelectric microphone is integrated with a lid and a substrate that comprises an acoustic port opening.

19. A device, comprising:
a complementary metal-oxide-semiconductor (CMOS) substrate; and
a piezoelectric microphone formed on the CMOS substrate, the piezoelectric microphone comprising:
at least one piezoelectric layer; and
a conductive layer that is deposited on the at least one piezoelectric layer and is associated with at least one sensing electrode.

20. The device of claim 19, wherein the CMOS substrate comprises a set of via structures that is electrically coupled to the conductive layer.

21. The device of claim 19, wherein the at least one sensing electrode is electrically coupled to the CMOS substrate.

22. The device of claim 19, wherein an acoustic channel is formed in a portion of the CMOS layer.

23. A method, comprising:
depositing a first conductive layer on a microelectromechanical systems (MEMS) substrate layer;
depositing a piezoelectric layer on the first conductive layer;
depositing a second conductive layer on the piezoelectric layer, wherein the second conductive layer is associated with at least one sensing electrode; and
depositing a complementary metal-oxide-semiconductor (CMOS) layer on the second conductive layer, where a cavity of the CMOS layer contains the at least one sensing electrode.

24. The method of claim 23, further comprising forming the cavity of the CMOS layer via an etching technique.

25. The method of claim 23, further comprising forming an acoustic port in the MEMS substrate layer and forming a pressure equalization channel that acoustically couples the acoustic port to the cavity.

26. A method, comprising:
disposing a sacrificial layer on a complementary metal-oxide-semiconductor (CMOS) substrate layer;
disposing a bottom electrode layer and a piezoelectric layer on the sacrificial layer; and
disposing a top electrode layer on the piezoelectric layer, the sacrificial layer and a set of via structures to form an electrical connection to the CMOS substrate layer.

27. The method of claim 26, further comprising performing deposition after the disposing the sacrificial layer.

28. The method of claim 26, further comprising performing planarization after the disposing the sacrificial layer.
